(19) United States
(12) Patent Application Publication
(10) Pub. No.: US 2013/0214424 A1
(43) Pub. Date: Aug. 22, 2013

(54) STRUCTURE AND MANUFACTURING METHOD FOR REDUCING STRESS OF CHIP

(71) Applicants: Nien-Yu TSAI, Hsinchu City (TW); Hao YU, Hsinchu City (TW); Jui-Hung CHIEN, Hsinchu City (TW); Shih-Chien CHANG, Hsinchu City (TW)

(72) Inventors: Nien-Yu TSAI, Hsinchu City (TW); Hao YU, Hsinchu City (TW); Jui-Hung CHIEN, Hsinchu City (TW); Shih-Chien CHANG, Hsinchu City (TW)

(21) Appl. No.: 13/535,083

(22) Filed: Jun. 27, 2012

(30) Foreign Application Priority Data
Feb. 22, 2012 (TW) 101105734

(51) Int. Cl. H01L 23/498; H01L 21/768

(52) U.S. Cl. 257/774; 438/613; 257/E23.067; 257/E21.589

(57) ABSTRACT

The invention provides a structure and a manufacturing method thereof for reducing a stress of a chip. The structure comprises a through-silicon via (TSV), a plurality of reinforcing base and a plurality of base bodies. The reinforcing bases are disposed near and around the TSV. The base bodies are disposed near and around the TSV, and the base is disposed on a side of the reinforcing base. The reinforcing base or the base body does not connected with the TSV.

This application claims priority of No. 101105734 filed in Taiwan R.O.C. on Feb. 22, 2012 under 35 USC 119, the entire content of which is hereby incorporated by reference.

### BACKGROUND OF THE INVENTION

1. Field of the Invention

The invention relates to a structure of a chip and a manufacturing method thereof, and more particularly to a structure capable of reducing a stress of a chip and a manufacturing method thereof.

2. Related Art

A conventional stacked type chip using the through-silicon via (TSV) package technology tends to have the extremely high fracture rate after the chip is completed. This is mainly caused by the nonuniform stress distribution. Also, the significantly warpage phenomenon tends to occur before the fracture, and finally the crack is formed in the chip.

In general, the difference between the mechanical properties of the materials causes significantly different responses to the temperature. For example, the coefficient of thermal expansion of the tube wall inside the TSV is equal to about 17 ppm/° C., the coefficient of thermal expansion of the silicon chip is equal to about 2.3 ppm/° C., and the coefficient of thermal expansion of the silicon dioxide is about 0.5 ppm/° C. Due to the difference between the properties of many kinds of materials after assembly, the chip encounters the problem of thermal expansion in the heating and cooling processes, so that the materials inside the chip induce the extremely large internal stress due to the temperature change. When the internal stress is too large, the chip encounters the problem of the mechanical reliability, thereby generating the phenomenon such as fracture.

### SUMMARY OF THE INVENTION

An object of the invention is to provide a structure for reducing a stress of a chip.

Another object of the invention is to provide a structure for reducing a stress of a chip and a manufacturing method thereof.

Still another object of the invention is to provide a structure, which reduces a stress of a chip and can be manufactured using the existing manufacturing processes.

Yet still another object of the invention is to reduce a warpage phenomenon of a chip caused by the stress, and thus to save the cost.

An embodiment of the invention provides a structure for reducing a stress of a chip. The structure comprises a through-silicon via (TSV), a plurality of reinforcing bases and a plurality of base bodies. The reinforcing bases are disposed near and around the TSV. The base bodies are disposed near and around the TSV. The base body is disposed on one side of the reinforcing base. The reinforcing base or the base body does not connect with the TSV.

Another embodiment of the invention provides a manufacturing method for reducing a stress of a chip. The method comprises: disposing a through-silicon via (TSV) on a first substrate; disposing a plurality of reinforcing bases and a plurality of reinforcing connection wires concurrently in a process of winding the first substrate, so that the reinforcing bases and the reinforcing connection wires are disposed near and around the TSV; disposing a plurality of solder balls on the first substrate and disposing a plurality of base bodies concurrently, wherein the base bodies are disposed near and around the TSV and above the reinforcing bases; and stacking a second substrate above the first substrate.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematic illustration showing a structure capable of reducing a stress of a chip according to an embodiment of the invention.

FIG. 2 is a decomposed schematic illustration showing the structure of the invention disposed on a stacked type chip.

FIG. 3 is a top view showing the structure according to an embodiment of the invention.

FIG. 4 is a schematic illustration showing stresses of the structure for reducing the stresses of the chip according to an embodiment of the invention.

FIG. 5 is a top view showing reinforcing bases according to an embodiment of the invention.

FIG. 6 is a top view showing reinforcing bases according to an embodiment of the invention.

FIG. 7 is a top view showing reinforcing bases according to an embodiment of the invention.

FIG. 8 is a flow chart showing a manufacturing method for reducing the stress of the chip according to an embodiment of the invention.

FIG. 9A is a decomposed schematic illustration showing a structure for reducing the stress of the chip according to an embodiment of the invention.

FIG. 9B is a decomposed schematic illustration showing a structure for reducing the stress of the chip according to an embodiment of the invention.

FIG. 9C is a decomposed schematic illustration showing a structure for reducing the stress of the chip according to an embodiment of the invention.

FIG. 9D is a decomposed schematic illustration showing a structure for reducing the stress of the chip according to an embodiment of the invention.

### DETAILED DESCRIPTION OF THE INVENTION

The present invention will be apparent from the following detailed description, which proceeds with reference to the accompanying drawings, wherein the same references relate to the same elements.

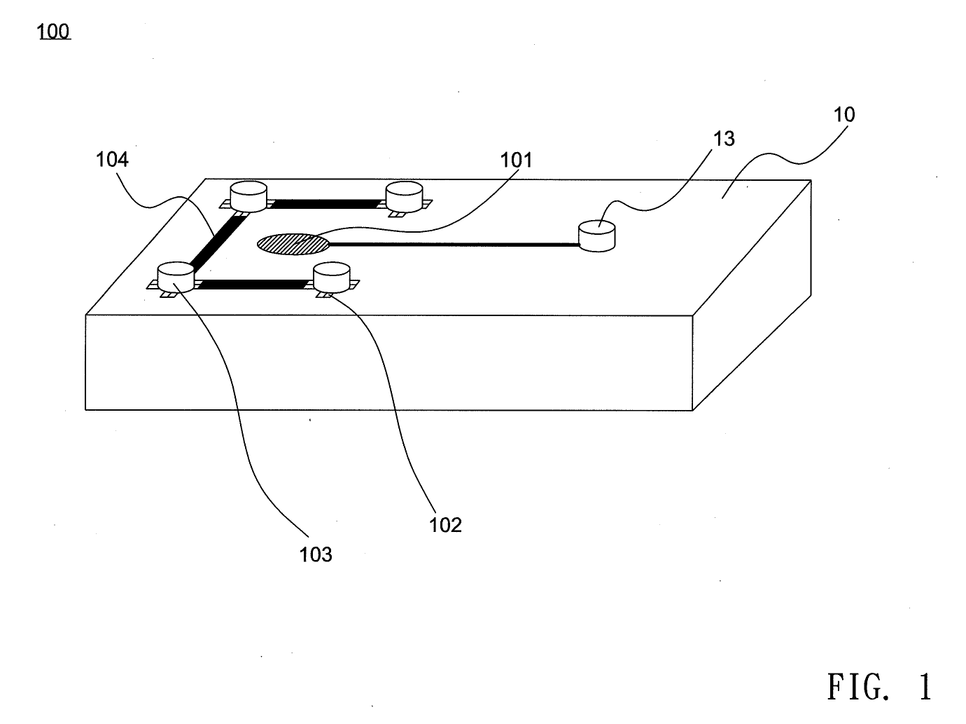

FIG. 1 is a schematic illustration showing a structure 100 capable of reducing a stress of a chip according to an embodiment of the invention. Referring to FIG. 1, the structure 100 of this embodiment is disposed on a stacked type chip, and comprises through-silicon vias (TSVs) 101, reinforcing bases 102 and base bodies 103.

It is to be noted that the structure 100 of the invention is disposed on a substrate 10, and the reinforcing bases 102 and the base bodies 103 are disposed near and around the TSV 101 of the structure 100. In addition, the structure 100 of this embodiment has four reinforcing bases 102 and four base bodies 103 disposed near and around each TSV 101. However, the invention should not be particularly restricted thereto, and the numbers of the reinforcing bases 102 and the base bodies 103 may also be increased or decreased according to the user's requirements.

The reinforcing bases 102 are disposed near and around the TSV 101. In one embodiment, a predetermined distance exists between the reinforcing base 102 and the TSV 101. In addition, the base body 103 is disposed on one side of the reinforcing base 102, and the base bodies 103 is disposed near and around the TSV 101. Also, in this embodiment, the structure 100 further comprises a plurality of reinforcing connection wires 104, and the reinforcing connection wire 104 connects the neighboring reinforcing bases 102 with each other, so the reinforcing connection wires 104 are also disposed near and around the TSV 101.

In addition, the reinforcing base 102 and the base body 103 of this invention may be implemented by various electroconductive materials with various geometric shapes. The reinforcing connection wire 104 may be implemented by a longitudinal metal. In one embodiment, the reinforcing base 102 is implemented by tin with the geometric shape, the base body 103 is implemented by copper or aluminum with the geometric shape, and the reinforcing connection wire 104 may be implemented by aluminum.

It is to be noted that the reinforcing base 102, the base body 103 and the reinforcing connection wire 104 in this invention do not connect with the TSV 101. In other words, the reinforcing base 102, the base body 103 and the reinforcing connection wire 104 neighboring the TSV 101 do not connect with the TSV 101.

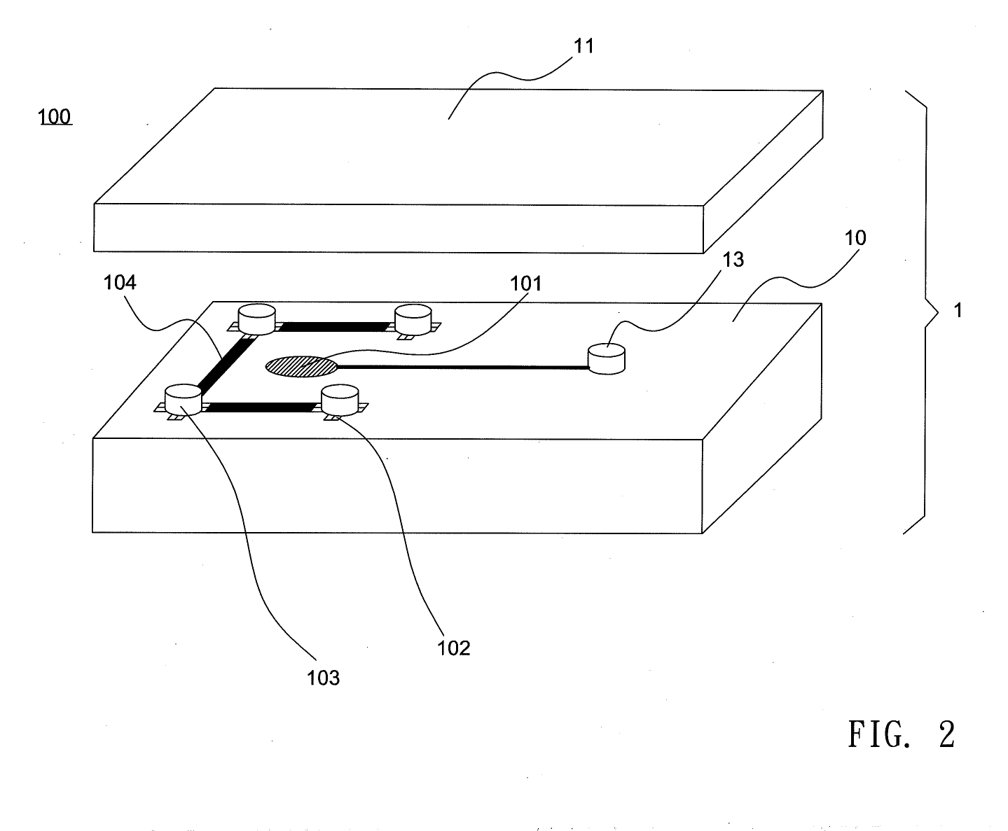

FIG. 2 is a decomposed schematic illustration showing the structure of the invention disposed on a stacked type chip. Referring to FIG. 2, the chip 1 has a substrate 10 and a substrate 11 stacked together, the reinforcing bases 102 of the structure 100 are disposed on the upper surface of the substrate 10, and the reinforcing bases 102 are disposed near and around the TSV 101.

Please note that, in one embodiment, the reinforcing bases 102 may also be disposed on the lower surface (not shown) of the substrate 11, or simultaneously disposed on the upper surface of the substrate 10 and the lower surface of the substrate 11. However, the invention should not be particularly restricted thereto. Consequently, the reinforcing connection wire 104 connects with the reinforcing base 102, so the reinforcing connection wire 104 is disposed on the upper surface of the substrate 10 or the lower surface of the substrate 11, and may also be simultaneously disposed on the upper surface of the substrate 10 and the lower surface of the substrate 11 corresponding to each other.

Because the reinforcing base 102 may be disposed on the upper surface of the substrate 10 or the lower surface of the substrate 11, the base body 103 may also be correspondingly disposed on one side of the reinforcing base 102. That is, when the reinforcing base 102 is disposed on the upper surface of the substrate 10, the base body 103 is disposed on the upper surface of the reinforcing base 102; and when the reinforcing base 102 is disposed on the lower surface of the substrate 11, the base body 103 is disposed on the lower surface of the reinforcing base 102.

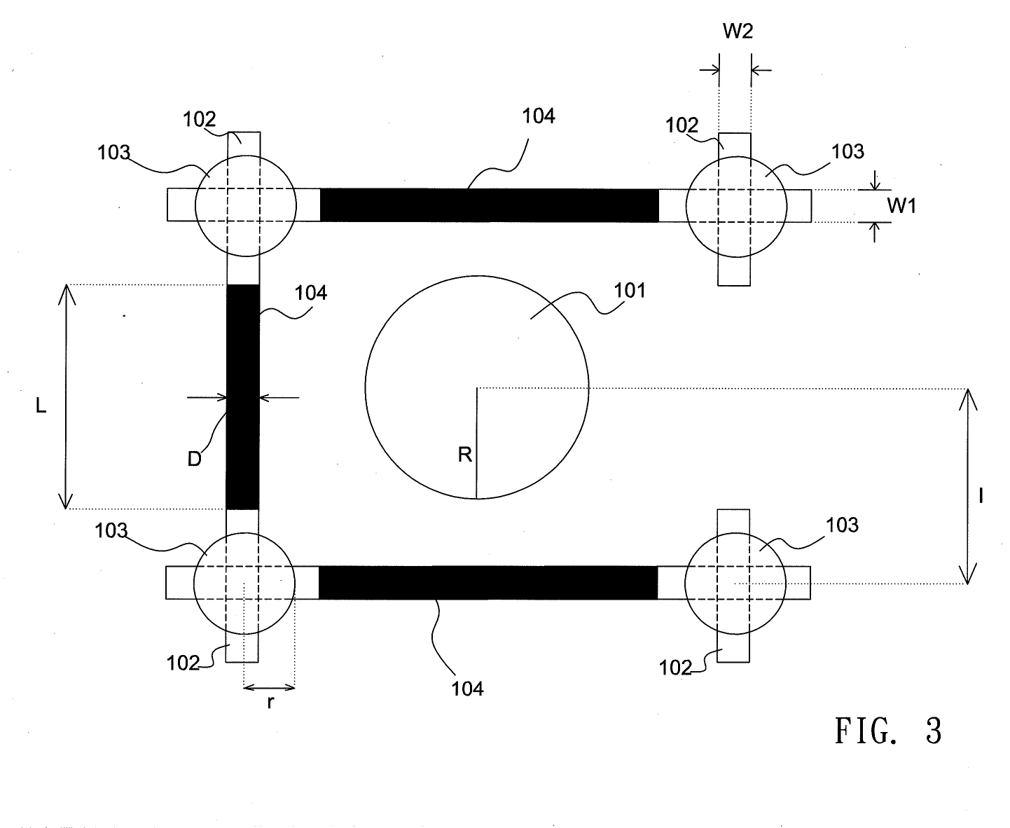

FIG. 3 is a top view showing the structure according to an embodiment of the invention. As shown in FIG. 3, it is assumed that a difference between a coefficient of thermal expansion of a material of a via wall of the TSV 101 and a coefficient of thermal expansion of the first substrate 10 is Δα, a temperature difference between the TSV 101 and the first substrate 10 is ΔT, a radius of the TSV 101 is R, a distance from a center point of the base bodies 103 to a center point of the TSV 101 is I, and a shape factor coefficient of the reinforcing connection wire 104 is B, then a stress σ of the first substrate 10 satisfies the following Equation (1) in one embodiment:

$$σ = - \frac{B \times Δ α \times Δ T}{2} \times {( \frac{R}{l} )}^{2} , \qquad ( 1 )$$

wherein, the reinforcing connection wire 104 has a shape factor coefficient B=μ×L²×D²×W²(R+1)², an adjustment factor μ, a length L, a width D and a height W. When the length L, the width D and the height W (not shown) of the reinforcing connection wire 104 are increased, it represents that the reinforcing connection wire 104 has the higher rigidity, so the stress of the substrate 10 is correspondingly reduced.

It is to be noted that if the radius of the reinforcing base 102 is r in this embodiment, then the radius R of the TSV 101 satisfies the following Equation (2):

0.2×R≦r (2).

In other words, the radius r of the reinforcing base 102 is larger than or equal to 0.2 times of the radius R of the TSV 101.

Also, the distance I from the center point of the base body 103 to the center point of the TSV 101 satisfies the following Equation (3):

0≦I≦3×(R+r) (3).

According to Equation (3), it is understood that, in one embodiment, three times of the sum of the radius R of the TSV 101 and the radius of the reinforcing base 102 is larger than the distance I from the center point of the base body 103 to the center point of the TSV 101.

In addition, the reinforcing base 102 has a first short side and a second short side when it is located on the upper surface of the substrate 10, and the length W₁ of the first short side satisfies the following Equation (4):

0≦W1 (4).

Also, the length W₂ of the second short side satisfies the following Equation (5):

W2≦5×R (5).

In Equation (5), five times of the radius R of the TSV 101 is larger than the length W₂ of the second short side.

In one embodiment of the invention, the region within the circle defined by the center, which is the center point of the TSV 101, and the radius I may be regarded as the neighboring region of the TSV 101.

Herein, please note that a solder ball 13 is disposed on the substrate 10 in this embodiment but the solder ball 13 and the TSV 101 have the electrical connection relationship, and the distance d from the center point of the solder ball 13 to the center point of the TSV 101 is larger than the distance I from the center point of the base body 103 to the center point of the TSV 101. So, the solder ball 13 may be regarded as being disposed outside the neighboring region of the TSV 101.

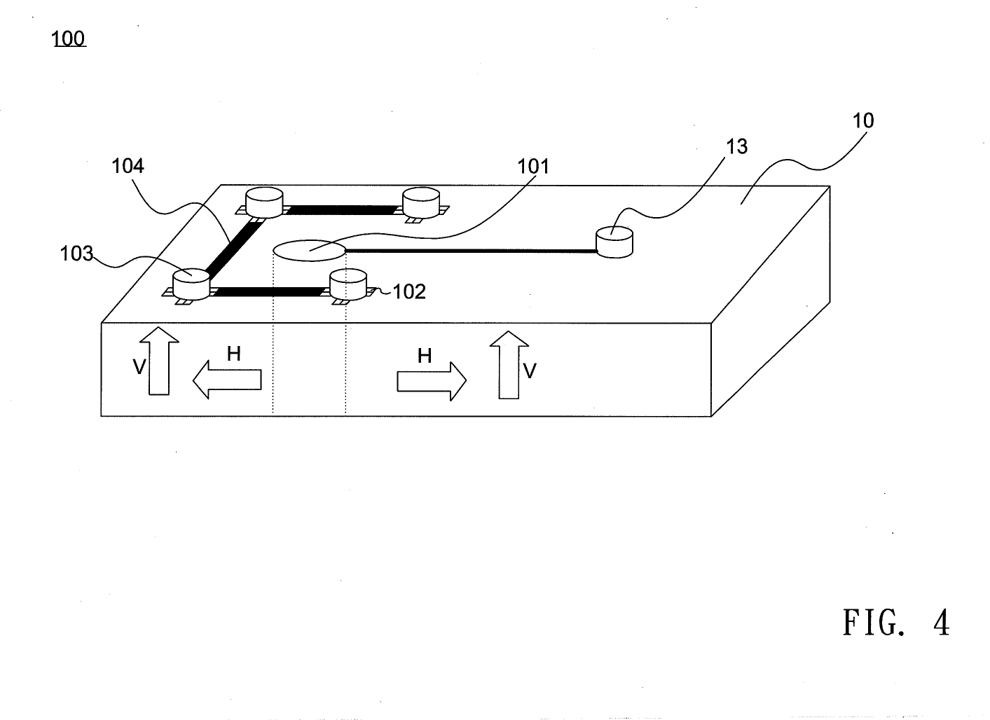

Please refer to FIGS. 1 and 4 simultaneously. FIG. 4 is a schematic illustration showing stresses of the structure for reducing the stress of the chip according to an embodiment of the invention. Because the coefficient of thermal expansion of the inner tube wall of the TSV 101 of the chip differs from the coefficient of thermal expansion of the substrate 10, the substrate 10 generates the warpage phenomenon during the temperature rising and falling processes. So, a transversal stress H and a longitudinal stress V are generated inside the substrate 10. However, the reinforcing connection wire 104 can increase the transversal rigidity of the substrate 10, and the base body 103 can also increase the longitudinal rigidity of the substrate 10, thereby reducing the transversal stress H and the longitudinal stress V generated inside the substrate 10 and preventing the warpage phenomenon from being caused.

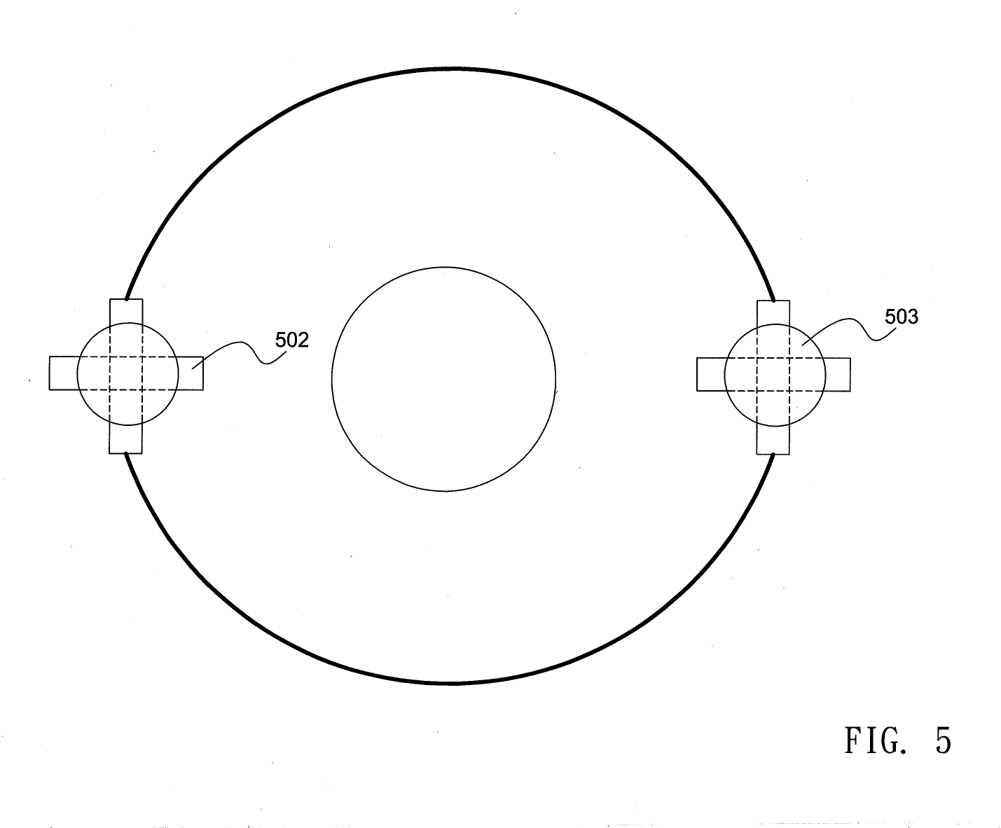

Next, please refer to FIG. 5. FIG. 5 is a top view showing reinforcing bases according to another embodiment of the invention. In this embodiment, each of two reinforcing bases 502 is formed by two rectangular longitudinal electroconductive materials intersecting with each other, and a base body 503 is a circular ball-shaped body.

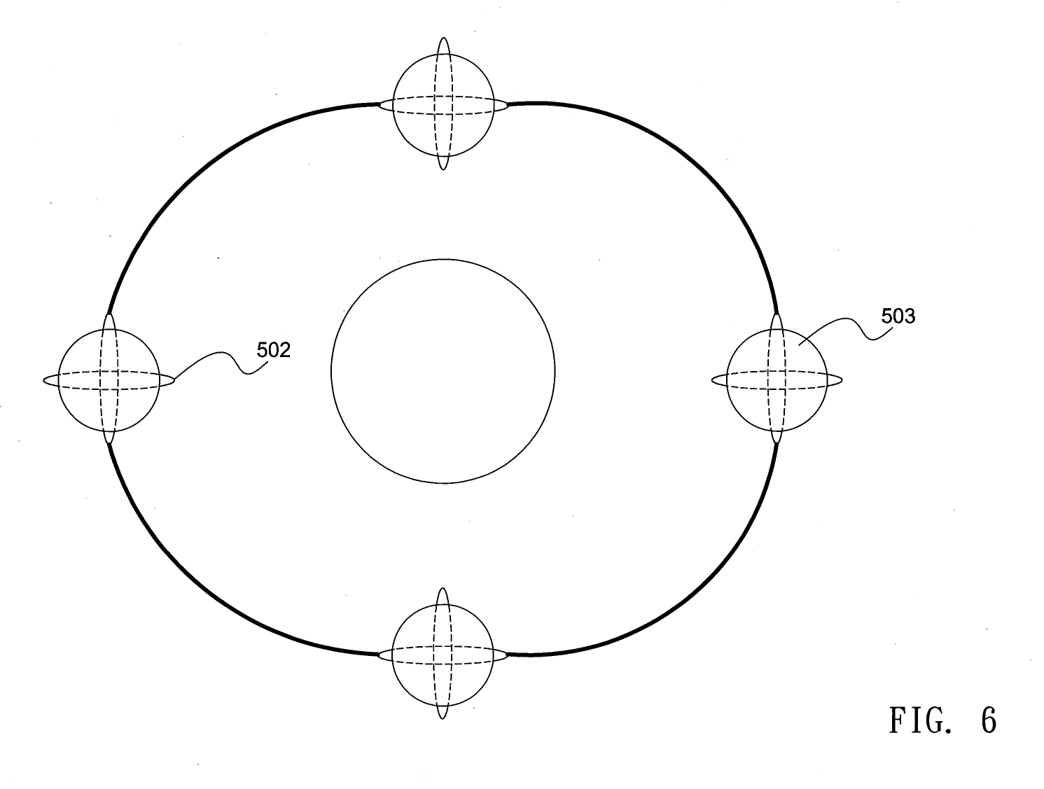

Please refer to FIG. 6. FIG. 6 is a top view showing reinforcing bases according to an embodiment of the invention. In this embodiment, each of two reinforcing bases 602 is formed by two elliptic longitudinal electroconductive materials intersecting with each other, and a base body 603 is a circular ball-shaped body.

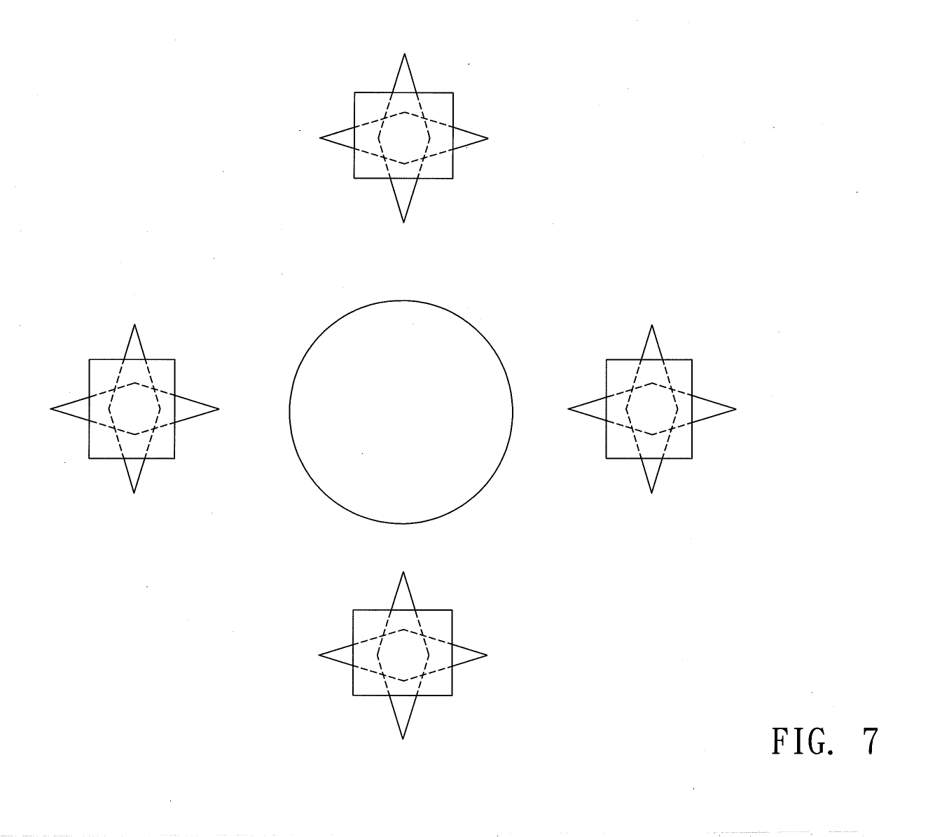

Please refer to FIG. 7. FIG. 7 is a top view showing reinforcing bases according to another embodiment of the invention. In this embodiment, the structure has four reinforcing bases 702, each of which is formed by four triangular electroconductive materials intersecting with each other, and a base body 703 is implemented by a rectangular base body.

Please refer to TABLE 1, which lists the implemented data according to an embodiment of the invention. According to TABLE 1, it is understood that the utilization of the reinforcing bases, the base bodies and the reinforcing connection wires of the invention can reduce the internal stress of the chip. In the structure of FIG. 5, the internal stress of the chip is reduced by 36.04% as compared with the internal stress of the conventional structure. In the structure of FIG. 6, the internal stress of the chip is reduced by 42.08% as compared with the internal stress of the conventional structure. In the structure of FIG. 7, although no reinforcing connection wire 704 connects with the reinforcing bases 702, the internal stress of the chip still can be reduced.

TABLE 1
implemented data of one embodiment of the invention

| | Conventional | Structure | Structure of | Structure |
|---|---|---|---|---|
| | chip structure | of FIG. 5 | FIG. 6 | of FIG. 7 |
| Maximum stress | 4.8 | 3.07 | 2.78 | 4.44 |
| (MPa) of the TSV | | | | |
| The reduced ratio | 0% | 36.04% | 42.08% | 7.5% |
| of the internal | | | | |
| stress of the chip | | | | |
| as compared with | | | | |
| the conventional | | | | |
| chip structure | | | | |

According to the above-mentioned experimental data, it is understood that the structure of the invention can effectively reduce the internal stress of the chip during the temperature rising and falling processes due to the difference between the properties of the materials.

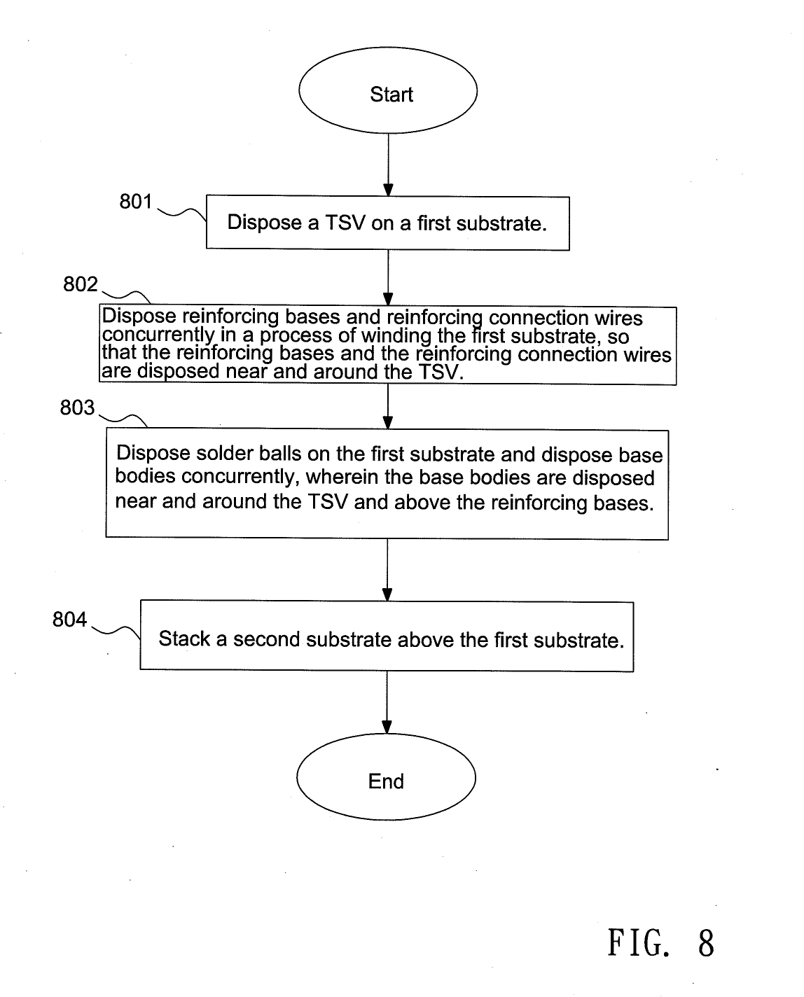

FIG. 8 is a flow chart showing a manufacturing method for reducing the stress of the chip according to an embodiment of the invention. The method includes the following steps.

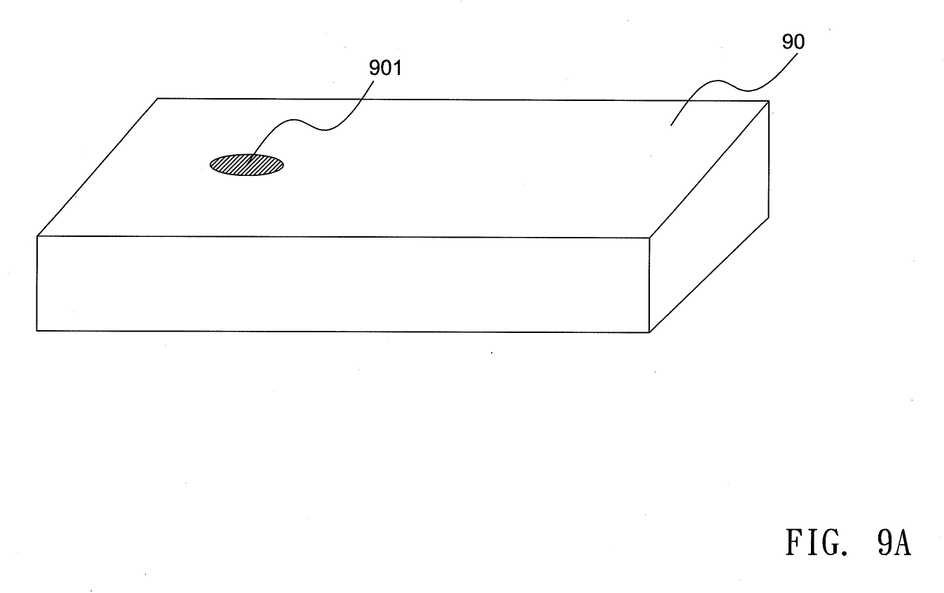

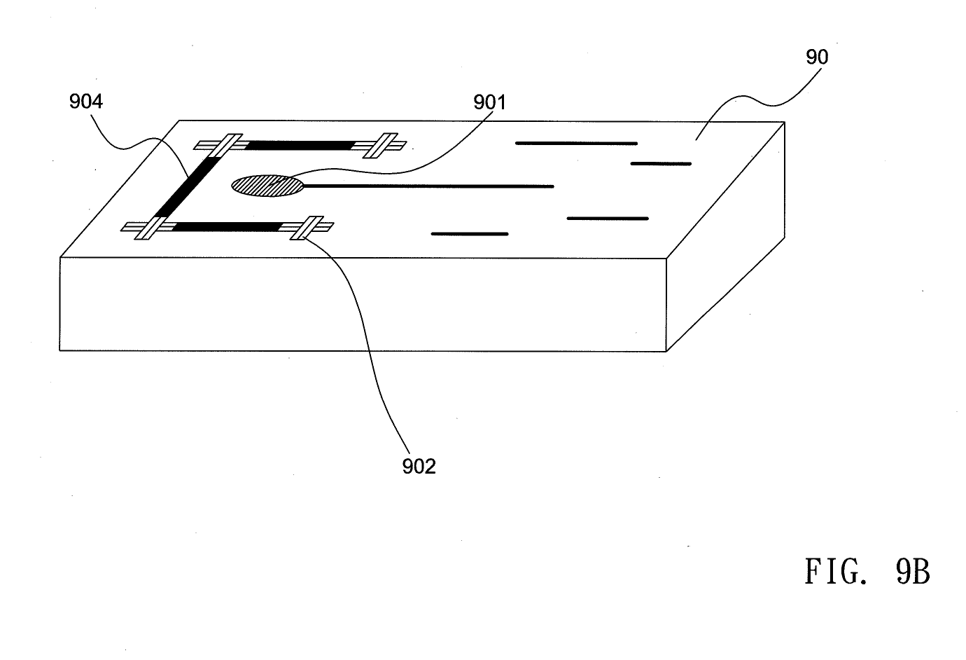

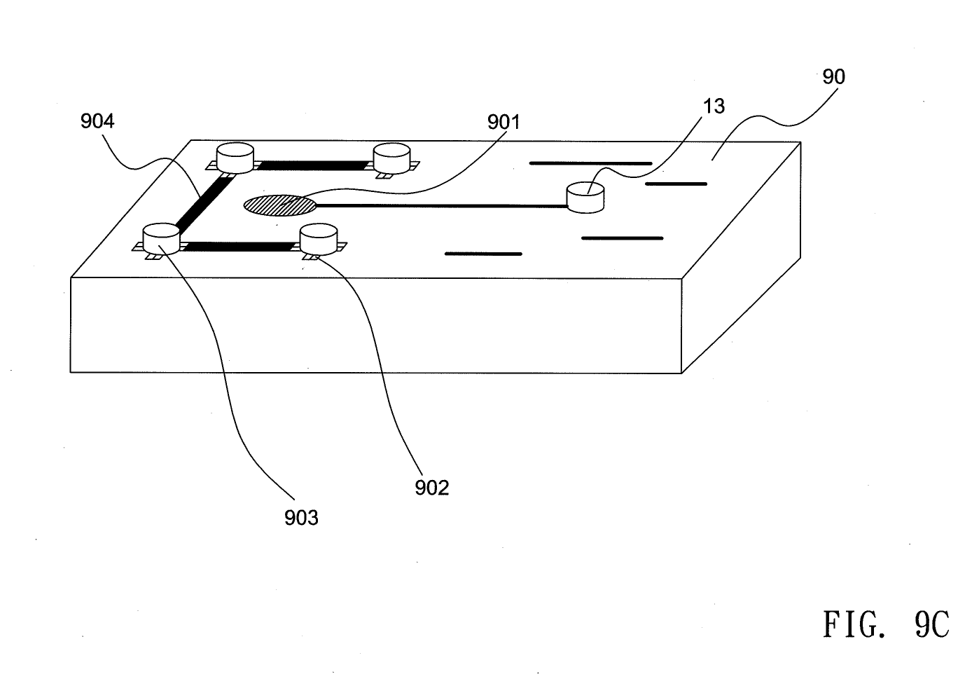

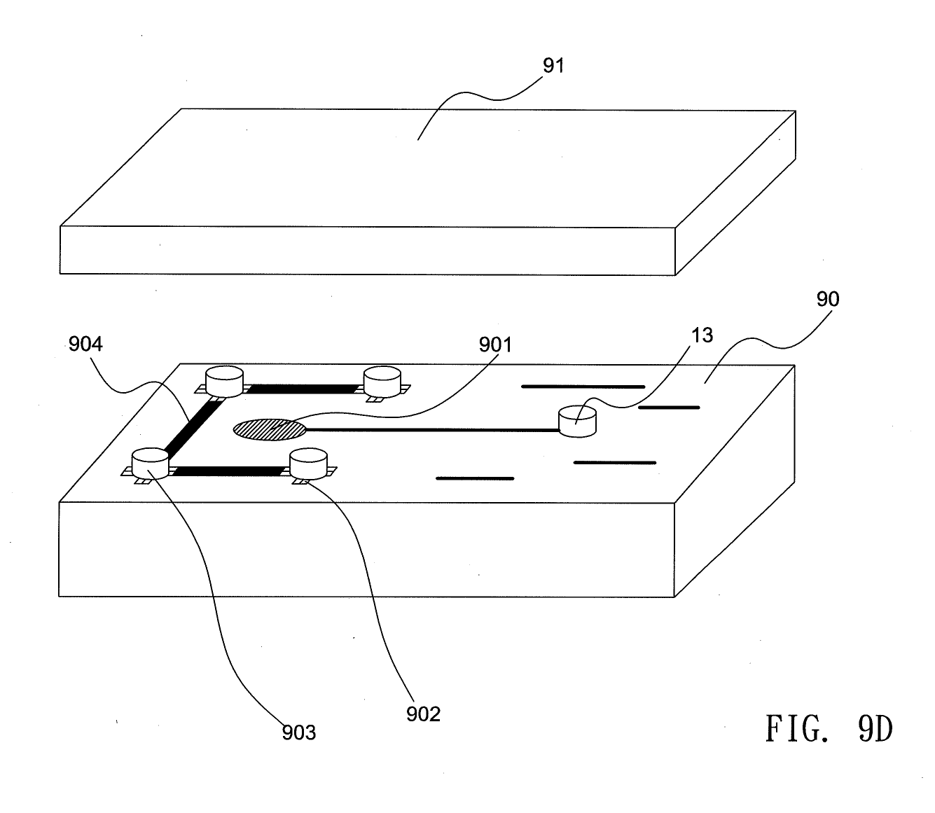

In step S801, a TSV 901 is disposed on a first substrate 90, as depicted in the decomposed schematic illustration of FIG. 9A.

In step S802, a plurality of reinforcing bases 902 and a plurality of reinforcing connection wires 904 are concurrently disposed when the layout of the first substrate is being performed, so that the reinforcing bases 902 surround the TSV 901, as depicted in the decomposed schematic illustration of FIG. 9B.

In step S803, a solder ball 13 and a plurality of base bodies 903 are simultaneously disposed on the first substrate 90, and the base bodies 903 are disposed near and around the TSV 901 and disposed above the reinforcing base 902, as depicted in the decomposed schematic illustration of FIG. 9C.

In step S804, a second substrate 91 is stacked above the first substrate 90, as depicted in the decomposed schematic illustration of FIG. 9D.

In summary, the conventional chip is assembled using a plurality of materials, but the difference between the properties of the materials after the assembling causes the chip to generate the extremely large internal stress during the temperature change in the temperature rising and falling processes. However, using the structures of the reinforcing bases, the base bodies and the reinforcing connection wires of the invention, and disposing the structures in the neighboring region of the TSV to surround the TSV can increase the transversal rigidity and the longitudinal rigidity of the chip, thereby preventing the chip from being damaged by the warpage phenomenon.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

1. A structure for reducing a stress of a chip, the structure comprising:
a through-silicon via (TSV);
a plurality of reinforcing bases, disposed near and around the TSV; and
a plurality of base bodies disposed near and around the TSV, wherein the base body is disposed on one side of the reinforcing base;
wherein the reinforcing bases or the base bodies do not connect with the TSV.

2. The structure according to claim 1, wherein the reinforcing base is an electroconductive material with a geometric shape.

3. The structure according to claim 1, wherein the reinforcing base connects with the base body.

4. The structure according to claim 2, wherein the structure comprises a plurality of reinforcing connection wires, the reinforcing connection wires connect with the neighboring reinforcing bases, the reinforcing connection wires surround the TSV, and the reinforcing connection wires do not connect with the TSV.

5. The structure according to claim 4, wherein the reinforcing bases are disposed on an upper surface of a first substrate of a stacked type chip or a lower surface of a second substrate; the reinforcing connection wires are disposed on the upper surface of the first substrate or the lower surface of the second substrate; the base bodies are disposed between the upper surface of the first substrate and the lower surface of the second substrate; and the base body is disposed on an upper surface of the reinforcing base or the lower surface of the reinforcing base.

6. The structure according to claim 5, wherein the reinforcing connection wires increase a transversal rigidity of the first substrate, and the base bodies increase a longitudinal rigidity of the first substrate.

7. The structure according to claim 5, wherein a difference between a coefficient of thermal expansion of a material of a via wall of the TSV and a coefficient of thermal expansion of the first substrate is Δα, a temperature difference between the TSV and the first substrate is ΔT, a radius of the TSV is R, a distance from a center point of the base bodies to a center point of the TSV is 1, and a shape factor coefficient of the reinforcing connection wire is B, then a stress σ of the first substrate satisfies the following equation:
$$σ = - \frac{B \times Δ α \times Δ T}{2} \times {( \frac{R}{l} )}^{2}$$
wherein the shape factor coefficient B of the reinforcing connection wire is represented as B=μ×L²×D²×W²(R+1)², an adjustment factor of the reinforcing connection wire is μ, a length of the reinforcing connection wire is L, a width of the reinforcing connection wire is D and a height of the reinforcing connection wire is W, so the stress σ of the first substrate is correspondingly reduced when the length L, the width D and the height W of the reinforcing connection wire are increased.

8. The structure according to claim 7, wherein if a radius of the reinforcing base is r, then the radius R of the TSV satisfies 0.2×R≦r; a distance 1 from a center point of the base bodies to a center point of the TSV satisfies 0≦I≦3×(R+r); if the reinforcing base has a first short side and a second short side and a length of the first short side is W₁, then the length W₁ of the first short side satisfies 0≦W₁; and if a length of the second short side is W₂, then the length W2 of the second short side satisfies W₂≦5×R.

9. A manufacturing method for reducing a stress of a chip, the method comprising:
disposing a through-silicon via (TSV) on a first substrate;
disposing a plurality of reinforcing bases and a plurality of reinforcing connection wires concurrently in a process of winding the first substrate, so that the reinforcing bases and the reinforcing connection wires are disposed near and around the TSV;
disposing a plurality of solder balls on the first substrate and disposing a plurality of base bodies concurrently, wherein the base bodies are disposed near and around the TSV and above the reinforcing bases; and
stacking a second substrate above the first substrate.

10. The method according to claim 9, wherein the solder balls and the TSV have electrical connection relationship, and the base bodies, the reinforcing bases and the reinforcing connection wires do not connect with the TSV or the solder balls.

11. The method according to claim 9, wherein the reinforcing connection wires connect with the neighboring reinforcing bases.

12. The structure according to claim 3, wherein the structure comprises a plurality of reinforcing connection wires, the reinforcing connection wires connect with the neighboring reinforcing bases, the reinforcing connection wires surround the TSV, and the reinforcing connection wires do not connect with the TSV.

13. The structure according to claim 12, wherein the reinforcing bases are disposed on an upper surface of a first substrate of a stacked type chip or a lower surface of a second substrate; the reinforcing connection wires are disposed on the upper surface of the first substrate or the lower surface of the second substrate; the base bodies are disposed between the upper surface of the first substrate and the lower surface of the second substrate; and the base body is disposed on an upper surface of the reinforcing base or the lower surface of the reinforcing base.

14. The structure according to claim 13, wherein the reinforcing connection wires increase a transversal rigidity of the first substrate, and the base bodies increase a longitudinal rigidity of the first substrate.

15. The structure according to claim 13, wherein a difference between a coefficient of thermal expansion of a material of a via wall of the TSV and a coefficient of thermal expansion of the first substrate is Δα, a temperature difference between the TSV and the first substrate is ΔT, a radius of the TSV is R, a distance from a center point of the base bodies to a center point of the TSV is 1, and a shape factor coefficient of the reinforcing connection wire is B, then a stress σ of the first substrate satisfies the following equation:
$$σ = - \frac{B \times Δ α \times Δ T}{2} \times {( \frac{R}{l} )}^{2}$$
wherein the shape factor coefficient B of the reinforcing connection wire is represented as B=μ×L²×D²×W²(R+1)², an adjustment factor of the reinforcing connection wire is μ, a length of the reinforcing connection wire is L, a width of the reinforcing connection wire is D and a height of the reinforcing connection wire is W, so the stress σ of the first substrate is correspondingly reduced when the length L, the width D and the height W of the reinforcing connection wire are increased.

16. The structure according to claim 15, wherein if a radius of the reinforcing base is r, then the radius R of the TSV satisfies 0.2×R≦r ; a distance 1 from a center point of the base bodies to a center point of the TSV satisfies 0≦I≦3×(R+r); if the reinforcing base has a first short side and a second short side and a length of the first short side is W₁, then the length W₁ of the first short side satisfies 0≦W₁; and if a length of the second short side is W₂, then the length W2 of the second short side satisfies W₂≦5×R.
